(19) United States
(12) Patent Application Publication
(10) Pub. No.: US 2011/0014577 A1
(43) Pub. Date: Jan. 20, 2011

(54) PELLICLE INSPECTION DEVICE, EXPOSURE APPARATUS USING SAME, AND DEVICE MANUFACTURING METHOD

(75) Inventor: Tsutomu Hashimoto, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/833,858

(22) Filed: Jul. 9, 2010

(30) Foreign Application Priority Data
Jul. 15, 2009 (JP) 2009-166495

(51) Int. Cl. G03B 27/54; G01H 13/00; G01N 21/01; G03F 7/20

(52) U.S. Cl. 430/325; 73/579; 356/237.2; 355/67

(57) ABSTRACT

The pellicle inspection device of the present invention is a device that detects damage to a pellicle film disposed on an original. The pellicle inspection device includes a measuring unit configured to measure a natural vibration frequency of the pellicle film, wherein the pellicle inspection device detects damage to the pellicle film based on the value of the natural vibration frequency measured by the measuring unit. In this case, the measuring unit includes, for example, a vibration inducing unit configured to induce vibration in the pellicle film, and a sensor that detects the vibration induced by the vibration inducing unit.

### BACKGROUND OF THE INVENTION

1. Field of the Invention

The present invention relates to a pellicle inspection device, an exposure apparatus using the same, and a device manufacturing method.

2. Description of the Related Art

An exposure apparatus is an apparatus that transfers a pattern of an original (reticle or mask) onto a photosensitive substrate (e.g., wafer, glass plate, and the like, where the surface thereof is coated with a resist layer) via a projection optical system in a lithography process in a manufacturing process of a semiconductor device, a liquid crystal display device, and the like. When foreign matter such as fine particles is present on the patterned surface of the original during transfer, foreign matter is also transferred simultaneously, resulting in an decrease in product yield. As a countermeasure to prevent this, for example, a protective film called a “pellicle” is affixed to the surface of a reticle in the semiconductor device manufacturing process in order to prevent foreign matter from adhering to the patterned surface of the reticle or to prevent foreign matter from adhering within the depth of field of a projection lens. With this arrangement, foreign matter of a certain size, which is adhering to the pellicle, is outside the depth of field, whereby the foreign matter is not imaged on a wafer.

However, if foreign matter, which adheres to a pellicle, has a comparatively large size (e.g., 60 μm or more), it may cause degradation of a reticle upon illumination, which may cause the production of defective products. Also, in the event of the breakage of a pellicle, foreign matter may be mixed in from the damaged point to thereby adhere to a patterned surface. Furthermore, a scratch made on a pellicle may cause the degradation of a reticle upon illumination as in the case of the foreign matter adhesion described above.

Accordingly, there have conventionally been proposed various devices that inspect whether or not foreign matter is adhering to a pellicle in advance. Japanese Patent Laid-Open No. 10-221270 discloses a foreign matter inspection device that emits a linearly polarized laser beam from one side to impinge obliquely on the pellicle film mounted on a stage, and causes a light receiving lens disposed in a vertical direction to receive scattered light from foreign matter adhering to the pellicle film for the determination of the presence of foreign matter. In addition, Japanese Patent Laid-Open No. 2003-315982 discloses a degradation identification method in which a pattern for identification is formed on a pellicle film to identify the degradation of the pellicle film from the results of measuring the pattern.

However, in the pellicle inspection devices disclosed in Japanese Patent Laid-Open No. 10-221270 and Japanese Patent Laid-Open No. 2003-315982, damage may not be detected depending on the degradation degree of a pellicle film. In this case, examples of damage to a pellicle film include scratches or breaks such as a hole, a recess, and the like. In particular, in the degradation identification method disclosed in Japanese Patent Laid-Open No. 2003-315982, a scratch or break cannot be detected without printing the pattern for identification on a pellicle film, therefore a special device needs to be introduced.

### SUMMARY OF THE INVENTION

In view of the foregoing, the present invention provides a pellicle inspection device that can readily detect scratches or breaks in a pellicle film regardless of the degradation degree of the pellicle film.

According to an aspect of the present invention, a pellicle inspection device that detects damage to a pellicle film disposed on an original is provided that includes a measuring unit configured to measure a natural vibration frequency of the pellicle film, wherein the pellicle inspection device detects damage to the pellicle film based on the value of the natural vibration frequency measured by the measuring unit.

According to the present invention, since damage on the pellicle film is detected based on the value of the natural vibration frequency of the pellicle film, damage such as scratches, breaks, or the like of the pellicle film can be readily detected regardless of the degradation degree of the pellicle film.

Further features of the present invention will become apparent from the following description of exemplary embodiments with reference to the attached drawings.

### BRIEF DESCRIPTION OF THE DRAWINGS

FIG. 1 is a schematic view illustrating the configuration of a pellicle inspection device according to a first embodiment of the present invention.

FIG. 2 is a view illustrating an exemplary reticle parameter.

FIG. 3 is a flowchart illustrating an inspection processing step according to the first embodiment.

FIG. 4 is a graph illustrating a history of the measurement result of a natural vibration frequency according to the first embodiment.

FIG. 5 is a schematic view illustrating the configuration of a pellicle inspection device according to a second embodiment of the present invention.

FIG. 6A is a schematic view (a sectional view of an inspection device) illustrating the configuration of a pellicle inspection device according to a third embodiment of the present invention.

FIG. 6B is a schematic view (a perspective view of an optical system) illustrating the configuration of a pellicle inspection device according to a third embodiment of the present invention.

FIG. 7 is a flowchart illustrating an inspection processing step according to the third embodiment.

FIG. 8A is a schematic view illustrating the configuration of the interior of an exposure apparatus according to a fourth embodiment of the present invention.

FIG. 8B is a schematic view illustrating an alternative configuration of the interior of an exposure apparatus according to the fourth embodiment of the present invention.

FIG. 9 is a flowchart illustrating an inspection processing step according to the fourth embodiment.

FIG. 10 is a graph illustrating a history of the measurement result of a natural vibration frequency according to other embodiment.

### DESCRIPTION OF THE EMBODIMENTS

Hereinafter, preferred embodiments of the present invention will now be described with reference to the attached drawings.

### First Embodiment

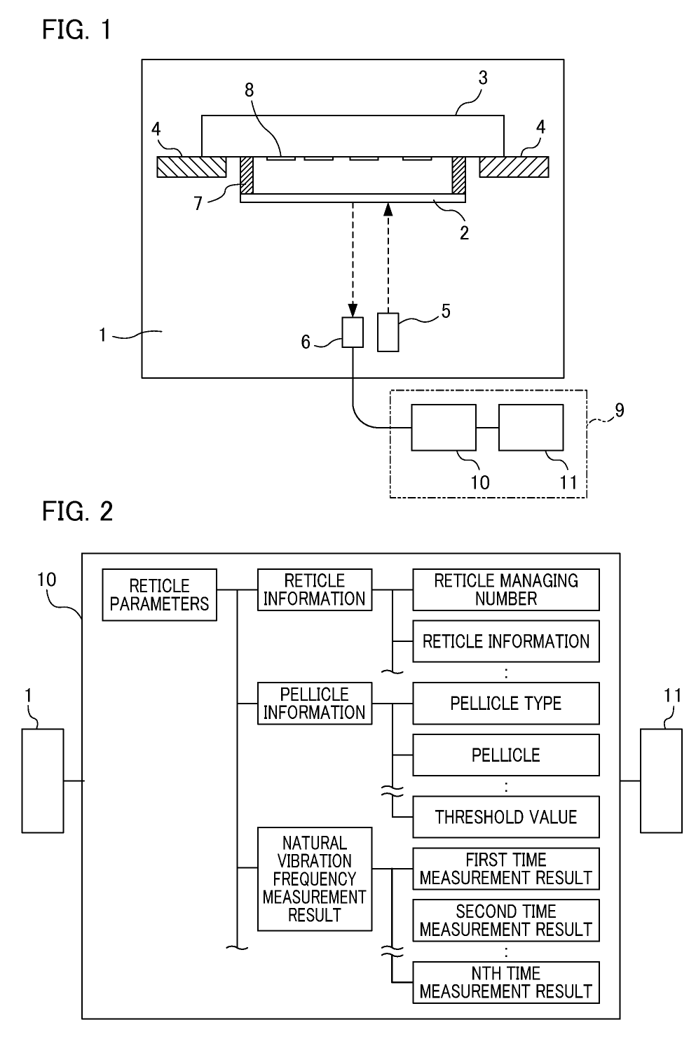

First, the configuration of a pellicle inspection device (hereinafter referred to as “inspection device”) according to a first embodiment of the present invention will now be described. FIG. 1 is a schematic view illustrating the configuration of a pellicle inspection device according to the first embodiment. It should be noted that the inspection device shown in FIG. 1 is a device dedicated to detection, which places a reticle with a pellicle film therein and detects damage to the pellicle film. An inspection device 1 includes the stage 4 on which a reticle 3 to which a pellicle film 2 is affixed is mounted, a sound source 5 disposed below the area in which the reticle 3 is mounted, and a microphone 6 disposed in the vicinity of the sound source 5.

The pellicle film 2 is a protective film that protects a pattern 8 formed on the surface of the reticle 3 and is affixed to a pellicle frame 7 made of aluminum alloy, which is fixed to the reticle 3, via an adhesive while maintaining a constant tension so as to prevent the looseness of the pellicle film 2. Also, the material of the pellicle film 2 is an organic material such as nitrocellulose or the like having elasticity.

The sound source 5 is a non-contact type vibration inducing unit configured to induce vibration in the pellicle film 2. In the present embodiment, the sound source 5 is capable of changing the vibration frequency of a sound wave radiated to the pellicle film 2. A sound wave is radiated to the pellicle film 2 while changing its vibration frequency as appropriate. At this time, the pellicle film 2 gradually starts vibration when the sound wave impinges it. When the vibration frequency of the sound source 5 is matched with the natural vibration frequency of the pellicle film 2, the amplitude gradually increases, and resonance is thereby started. The microphone 6 is a sound wave type sensor that detects vibration generated at the surface of the pellicle film 2. The microphone 6 detects the amplitude of the vibration of the pellicle film 2 and the vibration period and calculates the vibration frequency at which the maximum amplitude occurs as the natural vibration frequency of the pellicle film 2. The configuration in combination with the sound source 5 and the microphone 6 becomes a unit for measuring a vibration frequency of the pellicle film 2 according to the present embodiment.

Furthermore, the inspection device 1 includes a control section 9 that controls the operation of the sound source 5 and the microphone 6. The control section 9 further includes a storage unit 10 that stores the natural vibration frequency measured by the microphone 6, and an information processing unit 11 that processes vibration frequency measured data. The control section 9 controls the vibration frequency of the sound source 5 as well as manages the natural vibration frequency of the pellicle film 2 obtained for each measurement. The storage unit 10 is a storage unit configured by a magnetic storage medium, a memory, or the like, and stores the parameter (reticle parameter) of management information of the reticle 3 while the parameter corresponds one-to-one with the reticle 3. FIG. 2 is a view illustrating an exemplary reticle parameter to be stored in the storage unit 10. As shown in FIG. 2, the reticle parameters include reticle information, the measurement result of the natural vibration frequency of the pellicle film 2 described above, as well as a threshold value of pellicle information to be described below. The information processing unit 11 is an information processing unit configured by a computer with a CPU or the like that processes an inspection process to be described below in a program format as well as manages a history of the measurement result related to the pellicle film 2's natural vibration frequency stored in the storage unit 10.

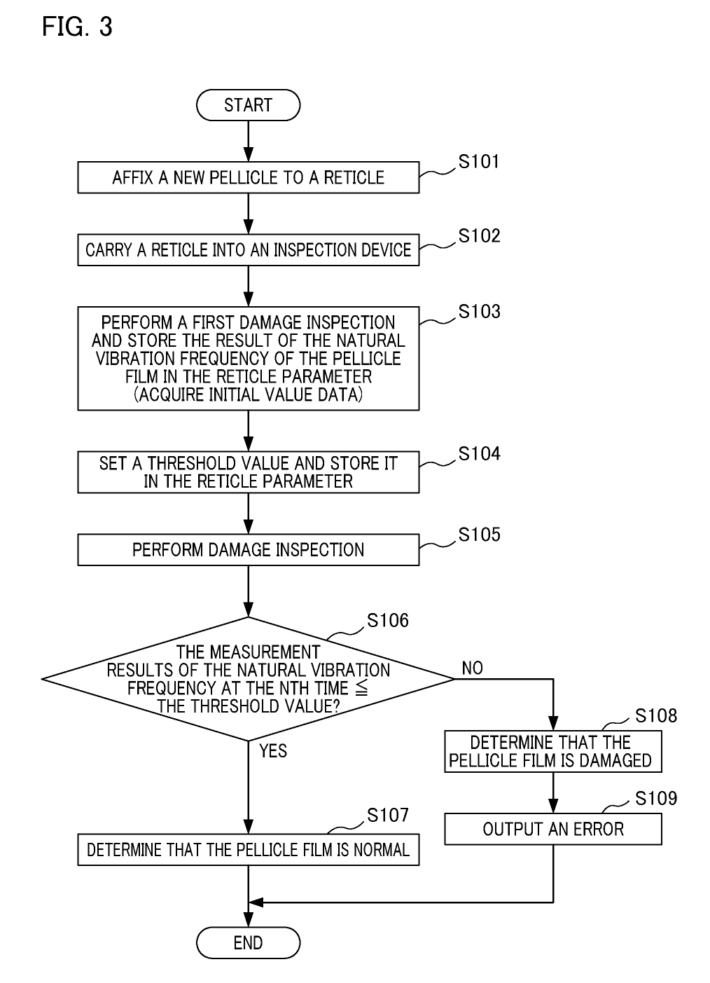

Next, the operation of the inspection device 1 of the present embodiment will now be described. In general, when the pellicle film 2 is ruptured, tension decreases, which causes a decrease in the natural vibration frequency. In addition, change in the natural vibration frequency occurs even when the pellicle film 2 is scratched or when the pellicle film 2 is distorted. Hence, the inspection device 1 of the present embodiment detects the change in the natural vibration frequency to thereby determine whether or not the pellicle film 2 has been damaged. Hereinafter, a pellicle film inspection (hereinafter referred to as “damage inspection”) processing step performed by the inspection device 1 will be described with reference to a flowchart of FIG. 3.

FIG. 3 is a flowchart illustrating a damage inspection processing step to be performed by the inspection device 1 of the present embodiment. First, for starting pellicle film inspection performed by the inspection device 1, a new pellicle is affixed to the reticle 3 (step S101), and the reticle 3 on which the pellicle film 2 is disposed is carried into the inspection device 1 (step S102). Next, the control section 9 radiates a sound wave of a first vibration frequency from the sound source 5 toward the pellicle film 2, and detects the vibration amplitude and the vibration period at the microphone 6 (step S103). At this time, the storage unit 10 stores the acquired vibration amplitude and vibration period as initial value data in the internal reticle parameter. Next, the control section 9 sets a certain vibration frequency value as a threshold value with reference to initial value data, and stores it in the reticle parameters (step S104). Next, the control section 9 repeatedly radiates a sound wave, of which the vibration frequency is changed each time, from the sound source 5 toward the pellicle film 2 until a certain time (Nth time), and the microphone 6 detects the vibration amplitude and the vibration period for each time (step S105). At this time, the value of N, i.e., a number of measurements (a number of repetitions) may be determined arbitrarily. During this time, the information processing unit 11 calculates the natural vibration frequency from the vibration amplitude and the vibration period that have been acquired from the microphone 6 to compare the calculated natural vibration frequency with a preset threshold value for each occasion (step S106). When the measurement results of the natural vibration frequency until the Nth time does not become equal to or less than the threshold value (YES in step S106), the control section 9 determines that the pellicle film 2 has not been damaged (step S107), and the inspection is ended. On the other hand, when the measurement results of the natural vibration frequency become equal to or less than the threshold value for a certain number of times (NO in step S106), the control section 9 determines that the pellicle film 2 has been damaged (step S108). In this case, the control section 9 provides an instruction to execute error output such as a screen display, a warning sound, or the like (step S109). Then, the inspection device 1 notifies the user about the error, and the inspection is ended.

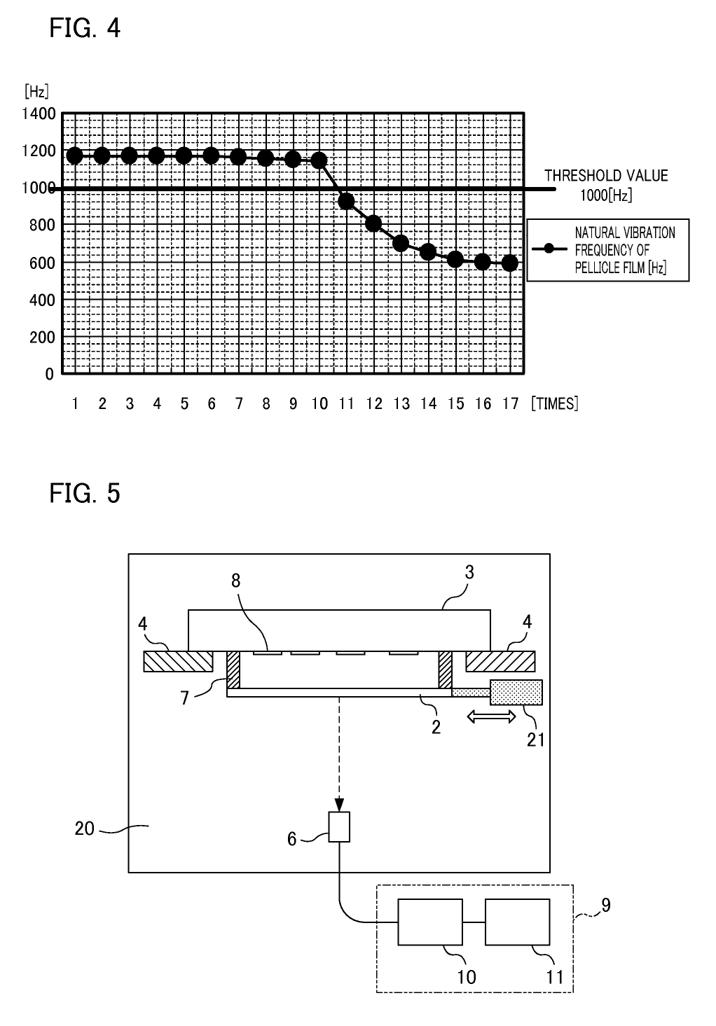

Next, the aforementioned damage inspection processing step will be described with reference to the specific example. FIG. 4 is a graph illustrating a history of the measurement result of a natural vibration frequency related to a pellicle film to be inspected, which is managed by the control section 9 during inspection. In FIG. 4, the measured natural vibration frequency [Hz] is plotted on the vertical axis, and the measurement time [Time] is plotted on the horizontal axis. Note that in this example, the user sets a number of measurements to 17 times. First, in step S103 of FIG. 3, the control section 9 calculates the value of 1200 Hz as the natural vibration frequency for the first time, and stores it as the initial value data in the reticle parameter. Next, in step S104, the control section 9 sets 1000 Hz as the threshold value, which is slightly smaller than the value of 1200 Hz, i.e., the initial value data, and stores it in the reticle parameter. In step S106, the control section 9 repeats measurements while changing the vibration frequency of a sound wave radiated by the sound source 5 for each time. Consequently, a change of the natural vibration frequency of the pellicle film 2 is seen from the measurement from the 11th time, and thus the control section 9 detects that the values of the subsequently measured natural vibration frequency are below the threshold value. Hence, the control section 9 transitions to step S108, and determines that some kind of damage is present on the pellicle film 2.

As described above, according to the present embodiment, since determination of the presence of damage on the pellicle film 2 is implemented based on the change of the natural vibration frequency of the pellicle film 2, damage such as scratches, breaks, or the like of the pellicle film 2 can be readily detected regardless of the degradation degree of the pellicle film 2.

### Second Embodiment

Next, the configuration of an inspection device according to a second embodiment of the present invention will now be described. FIG. 5 is a schematic view illustrating the configuration of an inspection device according to a second embodiment. It should be noted that the inspection device shown in FIG. 5 is a device dedicated to the detection of damage to the pellicle film as in the first embodiment, and the same elements as those shown in FIG. 1 are designated by the same reference numerals and the explanation thereof will be omitted. In the inspection device 20 of the present embodiment, the configuration of the vibration inducing unit configured to induce vibration of the pellicle film 2 is different from that employed in the inspection device 1 of the first embodiment. In other words, while, in the first embodiment, a non-contact type sound source is employed as the vibration inducing unit, the present embodiment is characterized in that a contact type vibration inducing unit is employed.

As shown in FIG. 5, an inspection device 20 of the present embodiment includes an air cylinder 21, which is an impact generation unit, as a contact type vibration inducing unit. The air cylinder 21 can appropriately change applying pressure by the command from the control section 9. When a direct vibration is imparted to the pellicle film 2, the pellicle film 2 may be damaged. Hence, the air cylinder 21 is disposed such that pressure (striking power) is imparted to the side surface of the pellicle frame 7. In consideration of the adhesion force of the pellicle frame 7, the strength of the pellicle frame 7, and the like relative to the reticle 3, pressure to be applied by the air cylinder 21 is determined by experiment or simulation in advance such that the pellicle film 2 is not damaged together with the reticle 3. Furthermore, it is desirable that a contact portion consisting of a wear-resistant material such as Poly-Ether-Ether-Ketone (PEEK), polyoxymethylene (POM), fluorine resin, or the like be disposed at the distal end of the air cylinder 21 such that foreign matter is not introduced due to impact.

In the inspection device 20, the pellicle film 2 and the pellicle frame 7 are oscillated by pressure applied by the air cylinder 21. As in the first embodiment, the generated vibration propagates through air, and is detected by the microphone 6 disposed below the pellicle film 2. At this time, although the microphone 6 detects vibration in which the vibration components of the pellicle film 2 and the pellicle frame 7 are combined, the combined vibration frequency may be calculated by using an arithmetic unit such as an FFT analyzer (not shown) or the like separately disposed in the control section 9. Because the processing step for pellicle film inspection, the effect obtained by the inspection device 20, and the like are the same as those described in the first embodiment, no further description will be given here.

### Third Embodiment

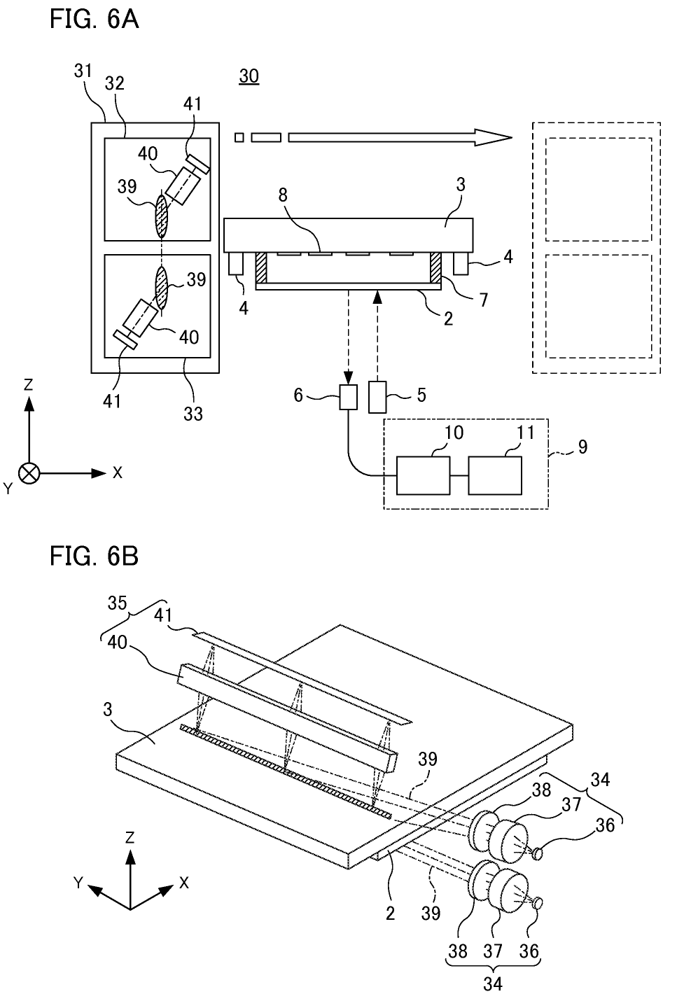

Next, the configuration of an inspection device according to the third embodiment of the present invention will now be described. Each of FIGS. 6A and 6B is a schematic view illustrating the configuration of an inspection device according to a third embodiment. FIG. 6A is a sectional view of an inspection device, and FIG. 6B is a perspective view of an optical system. In contrast to the inspection device of the first embodiment, the inspection device 30 of the present embodiment further includes a foreign matter inspection section having a horizontally movable optical system, and is characterized in that the detection of damage on the pellicle film 2 (damage inspection) is performed together with the detection of foreign matter on the surface of the reticle 3 (foreign matter inspection). Hereinafter, since the configuration for the damage inspection of the pellicle film 2 is similar to that of the first embodiment, the same elements as those shown in FIG. 6 are designated by the same reference numerals and the explanation thereof will be omitted.

First, the configuration of a foreign matter inspection section 31 will now be described. The foreign matter inspection section 31 includes a first optical system unit 32 that moves along the upper portion (blank surface) of the reticle 3 mounted on the stage 4, and a second optical system unit 33 that moves along the lower portion (pellicle surface) of the reticle 3. The foreign matter inspection section 31 further includes a drive section consisting of a ball screw or a belt pulley which simultaneously and horizontally moves on the blank surface and the pellicle surface, both of which are the surfaces to be inspected, so as to sandwich the reticle 3, whereby foreign matter can be inspected by a single scanning operation. The configuration of the first optical system unit 32 is the same as that of the second optical system unit 33. Hereinafter, a description of the first optical system unit 32 will be given, the same elements as those of the second optical system unit 33 shown in FIG. 6A are designated by the same reference numerals.

The first optical system unit 32 includes illumination system units 34 as illumination units that project light, and a reception system unit 35, which serves as a detection unit. The illumination system unit 34 includes a semiconductor laser 36, a collimator lens 37, and a wave plate 38. The semiconductor laser 36 causes an irradiating light 39, i.e., a linearly polarized light, to impinge obliquely on the surface of the reticle 3 mounted on the stage 4 via the collimator lens 37 and the wave plate 38. By disposing an optical element such as a beam splitter or the like, one of the illumination system units 34 may be shared with the second optical system unit 33 so that irradiating light is split between the blank surface and the pellicle surface. The reception system unit 35 includes an array lens 40, a line sensor 41, and a lens barrel (not shown) that holds the array lens 40 and the line sensor 41. The array lens 40 is an optical element that focuses scattered light emitted from foreign matter, when the foreign matter is present and the irradiating light 39 is irradiated on the foreign matter. Also, the line sensor 41 is a CMOS sensor that converts the scattered light output into a voltage for detection. It should be noted that a plurality of the reception system units 35 may be separately disposed on the blank surface and the pellicle surface. Here, the positional relationship between the illumination system unit 34 and the reception system unit 35 provides a significant contribution to the accuracy of the foreign matter detection. In particular, since the distance (height direction) between the pellicle surface and the second optical system unit 33 may change depending on the relationship between the pellicle film 2 and the pellicle frame 7, the second optical system unit 33 is appropriately adjusted in advance.

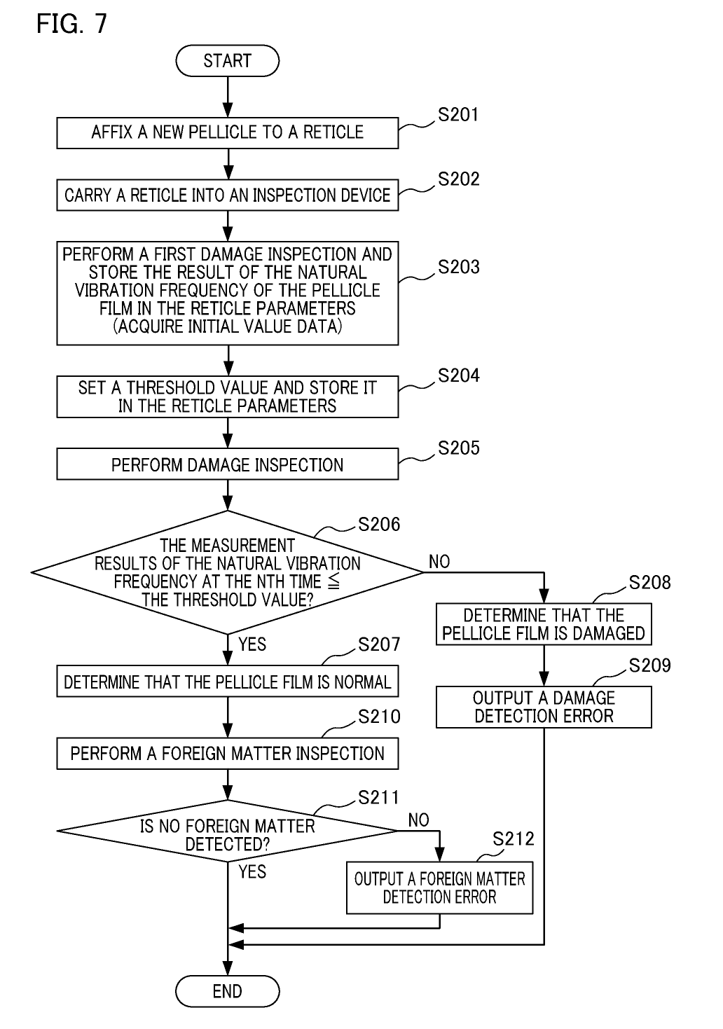

Next, the operation of the inspection device 30 according to the present embodiment will now be described. In the present embodiment, first, damage inspection of a pellicle film described in the first embodiment is performed, and then foreign matter inspection is performed by the foreign matter inspection section 31. FIG. 7 is a flowchart illustrating processing steps of the damage inspection and the foreign matter inspection of a pellicle film performed by the inspection device 30 of the present embodiment. Among the present processing steps, since the steps from step S201 to S209 are the same as the processing steps (steps S101 to S109) of the first embodiment shown in FIG. 3, no further description will be given here. First, when the control section 9 determines in step S207 that the pellicle film 2 has not been damaged, the control section 9 then provides an instruction to drive the foreign matter inspection section 31, and performs an inspection as to whether or not foreign matter adheres to the blank surface and the pellicle surface of the reticle 3 (step S211). Here, if no foreign matter is detected (YES in step S211), the inspection device 30 terminates the inspection. On the other hand, if foreign matter is detected (NO in step S211), the control section 9 provides an instruction to execute error output such as a screen display, a warning sound, or the like (step S212). Then, the inspection device 30 notifies the user about the error, and the inspection is ended. As shown in FIG. 7, when the control section 9 determines in step S208 that the pellicle film 2 has been damaged, the control section 9 immediately executes the error output, and thus the inspection device 30 terminates the inspection without performing a foreign matter inspection. This is not only because when the pellicle film 2 has been damaged, the reticle 3 cannot be employed in the subsequent device manufacturing steps regardless of the presence or absence of foreign matter, but also because it is effective in reducing the total inspection time of the inspection device 30.

As described above, according to the present embodiment, in addition to the same effects as those obtained by the first embodiment which detects damage such as scratches, breaks, or the like of the pellicle film 2, a foreign matter inspection, which detects the presence of foreign matter on the surface of the reticle 3, can also be performed by the inspection device.

### (Exposure Apparatus)

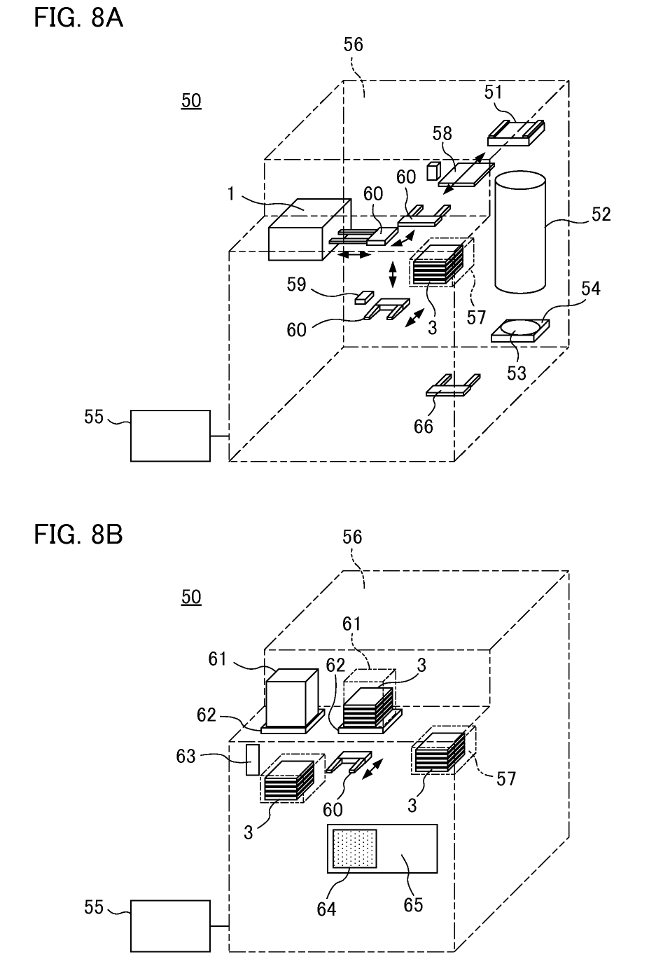

Next, an exposure apparatus to which the inspection device of the aforementioned embodiments is applied will now be described. Each of FIGS. 8A and 8B is a schematic view illustrating the configuration of an exposure apparatus. In particular, FIG. 8A is a schematic view illustrating the configuration of the interior of an exposure apparatus, and FIG. 8B is a schematic view illustrating an alternative configuration of the interior of an exposure apparatus. The exposure apparatus according to the present embodiment is an apparatus that is used in the semiconductor device manufacturing process and carries out an exposure process on a wafer, i.e., a substrate to be treated, and is a scanning type projection exposure apparatus that employs a step-and-repeat method or a step-and-scan method. The exposure apparatus 50 includes an illumination optical system (not shown) that irradiates illumination light, a reticle stage (original stage) 51 that holds a reticle 3, a projection optical system 52, a wafer stage (substrate stage) 54 that holds a wafer 53, and a control unit 55 that controls constituent elements within the apparatus. With the aid of a chamber 56, the exposure apparatus 50 is put in an environment that is distinct from the environment in a clean room at which the exposure apparatus 50 is to be installed, whereby temperature, air pressure, cleanliness, and the like are managed.

In addition, the exposure apparatus 50 includes the inspection device described in the aforementioned embodiments in the interior thereof. In the exposure apparatus 50, the inspection device 1 described in the first embodiment is included as an example. Furthermore, the exposure apparatus 50 includes a reticle storing shelf 57, an alignment station 58, an ID reading device 59, and a plurality of conveying robots 60 that carries in and out the reticle 3 between these constituent elements and the inspection device 1 in the interior thereof. The alignment station 58 is a stage that performs the positioning of the reticle 3, when the reticle 3 is mounted on the reticle stage 51. The ID reading device 59 is a device that reads a pattern such as a barcode printed on the reticle 3 for registration or confirmation of the reticle ID.

When an exposure process is performed, first, the reticle 3 is placed on a plurality of load ports 62 located in a planar direction with a single or a plurality of the reticle 3 being accommodated in a reticle carrier 61. Next, an elevator mechanism 63 disposed within the exposure apparatus 50 lowers the reticle carrier 61 on the load port 62, and carries it into the exposure apparatus 50. At this time, the reticle 3 is in its bare state, so that the conveying robots 60 can access the reticle 3. The conveying robots 60 appropriately convey the reticle 3 to the reticle stage 51, the reticle storing shelf 57, the alignment station 58, the ID reading device 59, or the inspection device 1. Here, a user may confirm through a monitor 64 disposed on the wall surface of the exposure apparatus 50 to provide an instruction about the place to which the conveying robots 60 conveys the reticle 3 from an operation panel 65, or the control unit 55 may automatically control such operation in a programmed way.

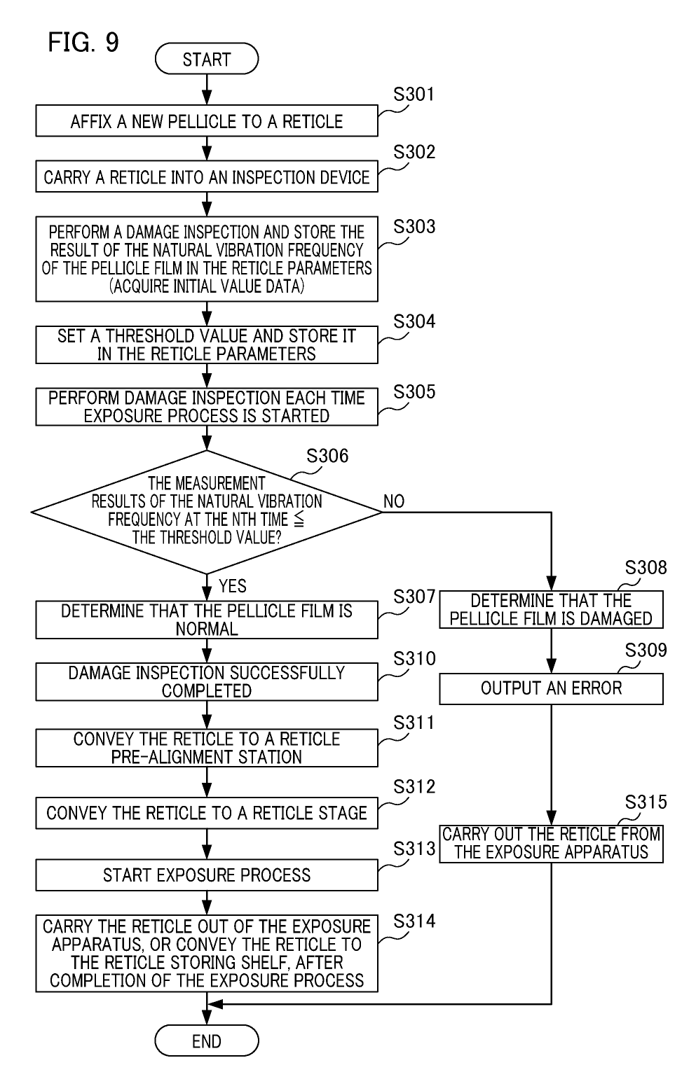

Next, the operation of the exposure apparatus 50 of the present embodiment will now be described. In the present embodiment, when the reticle 3 is conveyed into the exposure apparatus 50, the exposure apparatus 50, first, performs damage inspection of a pellicle film as described in the first embodiment, and then performs a normal exposure process. FIG. 9 is a flowchart illustrating processing steps performed by the exposure apparatus 50 of the present embodiment. As shown in step S305 among the present processing steps, damage inspection is performed each time an exposure process is started. Since the steps from step S301 to S309 are substantially the same as the processing steps (steps S101 to S109) of the first embodiment shown in FIG. 3, no further description will be given here. First, when damage inspection is completed successfully (step S310), the control unit 55 conveys the reticle 3 to the alignment station 58, and performs the positioning of the reticle 3 with respect to the reticle stage 51 (step S311). Next, the control unit 55 conveys the reticle 3 to the reticle stage 51 (step S312), and simultaneously conveys the wafer 53, which is the substrate to be treated, to the wafer stage 54 by using the wafer conveying robot 66. Then, the control unit 55 transmits a command to start the exposure process to the constituent elements (step S313).

In step S313, the exposure apparatus 50 performs a normal exposure process. First, illumination light for exposure is irradiated from an illumination optical system to the reticle 3 mounted on the reticle stage 51. For example, an illumination light source is an excimer laser light having a wavelength of 193 nm. The irradiation area is a slit-like irradiation area which partially covers the pattern area of the reticle 3. The pattern corresponding to the slit section is reduced, for example, in size to ¼ of the original and is projected on the wafer 53 by the projection optical system 52. The reticle 3 and the wafer 53 are scanned relative to the projection optical system 52 to thereby transfer the pattern area of the reticle 3 onto a photoresist coated on the wafer 53. The scanning exposure is repeatedly performed relative to a plurality of transfer areas (shot) on the wafer 53. When the exposure process in step S313 is completed, the control unit 55 carries out the reticle 3 from the reticle stage 51, and then causes the conveying robots 60 to convey the reticle 3 to the reticle storing shelf 57 (step S314) to terminate processing.

On the other hand, when the control section 9 of the inspection device 1 outputs an error in step S309, the control unit 55 causes the conveying robot 25 to convey the reticle 3, in which damage is present on the pellicle film 2 thereof, to the reticle carrier 61, whereby the reticle 3 is carried out of the exposure apparatus 50 (step S315). Then, the exposure apparatus 50 terminates processing without performing a normal exposure process.

As described above, according to the exposure apparatus of the present embodiment, a damage inspection of a pellicle film (or a foreign matter inspection) can be performed within the exposure apparatus 50. With this arrangement, carrying the reticle 3 out of the exposure apparatus 50 for each pellicle film inspection becomes unnecessary, whereby damage such as scratches, breaks, or the like of the pellicle film 2 can be efficiently detected.

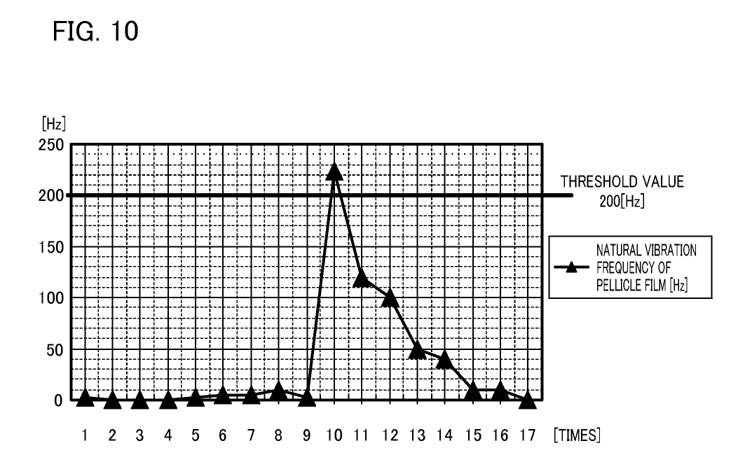

In setting a threshold value, while in the first embodiment, the control section 9 sets a certain vibration frequency value as a threshold value with reference to initial value data, the present invention is not limited thereto. For example, a user may calculate a threshold value by simulations in advance or may determine a threshold value by experiments in advance for setting with respect to the change in the natural vibration frequency of the pellicle film 2, based on the material of the pellicle film 2, the material of the pellicle frame 7, or a bonding method. In this case, when the information processing unit 11 has calculated that the difference between the measurement result of the natural vibration frequency at a certain time (Nth time) and the measurement result of the natural vibration frequency at the previous time ((N-1)th time) is equal to or more than the preset threshold value, the control section 9 determines that the pellicle film 2 has been damaged. FIG. 10 is a graph illustrating changes in the natural vibration frequency per unit time relating to a pellicle film to be inspected, which is managed by the control section 9 during inspection. In FIG. 10, a difference between the frequencies [Hz] is plotted on the vertical axis, and the number of measurements [Time] is plotted on the horizontal axis. In this example, a user sets the number of measurements to 17 times. In this case, instead of steps S103 and S104 shown in FIG. 3, a user acquires the value of 200 Hz as the difference of the natural frequencies calculated by simulations and the like, and stores it as the threshold value in the reticle parameter. In step S106, the control section 9 repeats measurements while changing the vibration frequency of a sound wave radiated by the sound source 5 each time. Consequently, a change of the natural vibration frequency of the pellicle film 2 is seen from the measurement at the 10th time, and thus the control section 9 detects that the value of the subsequently measured natural vibration frequency exceeds the threshold value. Hence, the control section 9 transitions to step S108, and determines that some kind of damage is present on the pellicle film 2.

Furthermore, an external vibration caused by the inspection device 1 may be measured with the reticle 3 not being installed on the inspection device 1 in advance. By creating in advance and then removing disturbance eliminating compensation data from the vibration result, which is the result of calculating vibration frequency of the pellicle film 2 or the vibration frequency of the pellicle film 2 and the pellicle frame 7, measurement errors are prevented, and thus the natural vibration frequency can be calculated with higher accuracy.

### (Device Manufacturing Method)

Next, a method of manufacturing a device (semiconductor device, liquid crystal display device, etc.) as an embodiment of the present invention is described. The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured through a process in which a transparent electrode is formed. The process of forming a plurality of transparent electrodes includes a step of coating a glass substrate with a transparent conductive film deposited thereon with a photoresist, a step of exposing the glass substrate coated with the photoresist to light using the above-described exposure apparatus, and a step of developing the exposed glass substrate. The device manufacturing method of this embodiment has an advantage, as compared with a conventional device manufacturing method, in at least one of performance, quality, productivity and production cost of a device.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-166495 filed Jul. 15, 2009 which is hereby incorporated by reference herein in its entirety.

What is claimed is:

1. A pellicle inspection device that detects damage to a pellicle film disposed on an original, the pellicle inspection device comprising:
a measuring unit configured to measure a natural vibration frequency of the pellicle film,
wherein the pellicle inspection device detects damage to the pellicle film based on the value of the natural vibration frequency measured by the measuring unit.

2. The pellicle inspection device according to claim 1, wherein the measuring unit further comprises a vibration inducing unit configured to induce vibration in the pellicle film, and a sensor that detects the vibration induced by the vibration inducing unit.

3. The pellicle inspection device according to claim 2, wherein the vibration inducing unit is a non-contact type sound source, and the sound source is capable of changing the vibration frequency of a sound wave radiated to the pellicle film.

4. The pellicle inspection device according to claim 2, wherein the vibration inducing unit is a contact type impact generation unit, and the impact generation unit is capable of changing pressure applied to a pellicle frame that holds the pellicle film.

5. The pellicle inspection device according to claim 2, wherein the sensor is a sound wave type, and calculates the natural vibration frequency based on the amplitude and the period of the vibration of a sound wave emitted from the pellicle film.

6. The pellicle inspection device according to claim 2, further comprising:
a control section that comprises a storage unit configured to store the value of the natural vibration frequency measured by the measuring unit and an information processing unit configured to process the value of the natural vibration frequency stored in the storage unit, and manages the measuring unit,
wherein the control section stores the natural vibration frequency obtained by the vibration inducing unit and a preset threshold value in the storage unit and causes the information processing unit to compare the measured natural vibration frequency with the threshold value for each occasion to thereby determine whether or not the pellicle film has been damaged.

7. The pellicle inspection device according to claim 6, wherein the threshold value is set based on the natural vibration frequency measured by the measuring unit for the first time, and the control section determines that the pellicle film has been damaged, when the information processing unit has calculated that the natural vibration frequency is equal to or less than the threshold value.

8. The pellicle inspection device according to claim 6, wherein the threshold value is calculated by simulations or experiments in advance based on the material of the pellicle film, and the control section determines that the pellicle film has been damaged, when the information processing unit has calculated that the difference between the measurement result of the natural vibration frequency at a certain time and the measurement result of the natural vibration frequency at a time prior to the certain time is equal to or more than the threshold value.

9. The pellicle inspection device according to claim 6, wherein the storage unit stores a history of the measurement result of the measured natural vibration frequency together with parameters for the management information of the original.

10. The pellicle inspection device according to claim 6, wherein the control section executes error output, when the information processing device has calculated that the natural vibration frequency exceeds the threshold value.

11. The pellicle inspection device according to claim 1, wherein the measuring unit measures an external vibration caused by the apparatus in advance with the original not installed.

12. The pellicle inspection device according to claim 1, further comprising:
a foreign matter inspection section comprising:
an illumination unit that causes irradiating light to impinge obliquely on a surface to be inspected for either a blank surface or a pellicle surface of the original;
a detection unit configured to detect scattered light emitted upon the irradiation of the irradiating light onto foreign matter deposited on the surface to be inspected; and
a drive section that scans the irradiation unit and the detection unit.

13. An exposure apparatus comprising:
an illumination optical system that illuminates an original;
an original stage that holds the original;
a projection optical system that guides light emitted from the original to a substrate to be treated;
a substrate stage that holds the substrate to be treated; and
a pellicle inspection device that detects damage to a pellicle film disposed on the original,
wherein the pellicle inspection device comprises a measuring unit configured to measure a natural vibration frequency of the pellicle film, and detects damage to the pellicle film based on the value of the natural vibration frequency measured by the measuring unit, and
wherein the original is mounted on the original stage after inspection by the pellicle inspection device.

14. A device manufacturing method comprising the steps of:
exposing a substrate using an exposure apparatus; and
developing the substrate,
wherein the exposure apparatus comprises:
an illumination optical system that illuminates an original;
an original stage that holds the original;
a projection optical system that guides light emitted from the original to a substrate to be treated;
a substrate stage that holds the substrate to be treated; and
a pellicle inspection device that detects damage to a pellicle film disposed on the original,
wherein the pellicle inspection device comprises a measuring unit configured to measure a natural vibration frequency of the pellicle film, and detects damage to the pellicle film based on the value of the natural vibration frequency measured by the measuring unit, and
wherein the original is mounted on the original stage after inspection by the pellicle inspection device.
